(19) United States
(12) Patent Application Publication
(10) Pub. No.: US 2018/0073133 A1
(43) Pub. Date: Mar. 15, 2018

(54) PERISHABLE ELEMENT FOR PARTICLE BOMBARDMENT, SET OF DEVICES FOR PARTICLE BOMBARDMENT AND PERISHABLE ELEMENT AND METHOD FOR DETERMINING THE ETCHING PATTERN VIA PARTICLE BOMBARDMENT OF A TARGET

(71) Applicant: ADVANCED NANOTECHNOLOGIES, S.L., Barcelona (ES)

(72) Inventors: Enric BERTRAN SERRA, Barcelona (ES); Roger AMADE ROVIRA, Barcelona (ES)

(21) Appl. No.: 15/563,856

(22) PCT Filed: Mar. 30, 2016
(86) PCT No.: PCT/ES2016/070220

§ 371 Date: Oct. 2, 2017

(30) Foreign Application Priority Data
Mar. 31, 2015 (ES) P 201530440

(51) Int. Cl. C23C 14/34; C23C 14/28

(52) U.S. Cl. CPC C23C 14/3407; C23C 14/28

(57) ABSTRACT

Fungible element (1) provided with a target (2) for particle bombardment, intended to carry out the vapour-phase physical deposition of a thin layer on a substrate (3), said fungible element (1) comprising a base layer (4) on which the target (2) is deposited, said target intended to be sputtered by the particle bombardment, wherein the target is formed by at least one layer (21) in which a plurality of zones (xᵢ, yᵢ) is defined, having an average thickness (eⱼ(xᵢ, yᵢ)) that is variable between the zones (xᵢ, yᵢ), said average thicknesses (eⱼ(xᵢ, yᵢ, )) of each zone (xᵢ, yᵢ) being dimensioned such that, in certain bombardment conditions, all the zones (xᵢ, yᵢ) have an identical ion sputtering time (tⱼ). The invention also refers to a particle bombardment device (5) and fungible element (1) set and to the process to obtain such fungible element (1).

### TECHNICAL FIELD

The present invention is framed in the thin film coatings sector, particularly achieved by particle bombardment.

### BACKGROUND OF THE INVENTION

Well known are the vapour-phase physical deposition tecniques for substrate thin film coating, consisting of bombarding a target with particles such as ions or photons, so that this target emits the coating particles (consisting of isolated atoms or few atoms clusters) that are transfered to the substrate to be coated.

To perform such coatings the process consists of setting a substrate in front of a particle source, estimating the appropriate amount of time needed to achieve a certain coating thickness and bombarding during a certain amount of time. The resulting coating thickness is highly dependent on bombardment time and therefore a very precise control of the bombardment time is essential to obtain the desired results

In other cases, more complex coatings might be desired, i.e. different coating materials or a multilayer coating. In such cases, different material targets must be placed sequentially, and likewise control bombardment times with precision, in order to achieve the desired coatings.

These are usual laboratory tasks and can be performed with satisfactory results. But, if the objective is to perform coatings on an industrial scale in order to market the coated products on a large scale, the aforementioned process can result in excessively expensive costs, especially if a high end quality is pursued.

Particularly, the uniformity of results will strongly depend of every facility, and especially much dependent on the control performed by the bombardment facility operator.

For this reason, the inventors reached the conclusion that there is a lack of solutions to reduce coating costs and guarantee an optimal coating quality at the same time, and very much especifically allow the dependancy reduction of a proper coating on bombardment time precision.

### DESCRIPTION OF THE INVENTION

To achieve that, the current invention proposes a fungible element provided with a target for the particle bombardment, intended to carry out the vapour-phase physical deposition of a thin layer on a substrate, said fungible element comprising a base layer on which the target is deposited, said target intended to be sputtered by the particle bombardment, wherein the target is formed by at least one layer (j) in which a plurality of zones (xᵢ, yᵢ) is defined, having an average thickness (eⱼ(xᵢ, yᵢ)) that is variable between the zones (xᵢ, yᵢ), said average thicknesses (eⱼ(xᵢ, yᵢ)) of each zone (xᵢ, yᵢ) being dimensioned such that, for determined bombardment conditions, all the zones (xᵢ, yᵢ) have an identical ion sputtering time tⱼ).

In this way it is possible to overcome the disadvantages of the state of the art. In fact, this fungible element allows the coating thickness to be dependent of a previously prepared element, instead of being totally dependent on real time parameter adjusting tasks performed by an operator. This allows coating stage industrialization of any coating type, either mono layer or multilayer, in any process using particle bombardment targets.

Thus the invention allows to eliminate the necessity to control both bombardment time and source power (assuming that the source footprint does not vary significantly with the power variation) to obtain neat interface multilayer structures, that is to say separation surfaces between different coating layers. The fungible element can be employed to produce optical interference multilayer deposition, mono layer or multilayer electric contact metallization, ultra-thin monolayer or multilayer structures—down to monoatomic thicknesses-, nano-island or nano-structure controlled deposits on a substrate, a previous stage to coalescence, among others.

The target will preferably be constituted by a plurality of layers.

Advantageously, the different (xᵢ, yᵢ) zones can be formed by the same material or by different materials.

The invention also refers to a set formed by a particle bombardment device and a fungible element provided with a target to be bombarded (with ions, neutral particles or photons) by the said particle bombardment device intended to carry out the vapour-phase physical deposition of a thin layer on a substrate intended to receive the deposition material disposed on the target, said fungible element comprising a base layer on which the target is deposited, said target intended to be sputtered by the particle bombardment, wherein the target is formed by at least one layer in which a plurality of zones (xᵢ, yᵢ) is defined, having an average thickness (eⱼ(xᵢ, yᵢ)) that is variable between the zones (xᵢ, yᵢ), said average thickness (eⱼ(xᵢ, yᵢ)) of each zone (xᵢ, yᵢ) being dimensioned such that, in certain bombardment conditions, all the zones (xᵢ, yᵢ) have an identical ion sputtering time (tⱼ), so that it is possible to control the thickness of the layer deposited on the substrate by the previous dimensioning of the target deposition material thicknesses (eⱼ(xᵢ, yᵢ)).

The target of the set will preferably be constituted by a plurality of layers.

Advantageously, in the set, the different (xᵢ, yᵢ) zones can be formed by the same material or by different materials.

As a variant, in the set, the bombardment is an ionic bombardment, i.e. performed by means of cathodic sputtering head or ion gun as well as neutral particle bombardment by means of a neutralized ion gun or plasma gun or similar techniques.

As another variant, in the set, in which the bombardment is a photonic bombardment in order to produce laser ablation (LAD) or photonic bombardment by means of pulsed laser (PLD) or by means of similar techniques.

Preferably, in the set, the head or gun comprises the means for changing its orientation so it is possible to orient it towards the target as well as the substrate, thus having the possibility of commuting between an ion or plasma gun assisted deposition mode and a compaction by direct bombardment mode.

The invention also refers to a process for the determination of an engraving pattern by target (2) particles bombardment, in order to obtain an engraving velocity and thickness (eⱼ(xᵢ, yᵢ) based on the position (x, y) of a fungible element according to any of the aforementioned fungible element variations, comprising the stages of:
a) Performing an homogeneous deposit of deposition material on a base layer to obtain an homogeneous thickness target;
b) Arranging on the target a resin mask, so that there are zones of the target that remain covered by the resin as well as zones that remain uncovered by the resin;
c) Arranging the resulting product during a certain amount of time, in a certain position and in front of a certain particle bombardment device to perform a vapour-phase physical deposition process of a thin layer on a substrate;
d) Removing the resin mask;
e) Measuring the local height differences between target resin covered points and non resin covered points;
f) Obtaining an engraving velocity function vⱼ(xᵢ, yᵢ) of the target for the aforementioned certain conditions;
g) Using the said engraving velocity function vⱼ(xᵢ, yᵢ) to determine the thickness (eⱼ(xᵢ, yᵢ) of the target in every position (x,y) so that the layer or layers (j) of the fungible element can be consumed one after another.

Preferably, in the inventivion process, the mask is a mesh.

Multilayer target fabrication can be performed by means of ink injection printers or printjet printers. These printers allow to reproduce point by point the thickness function eⱼ(xᵢ, yᵢ) determined by means of the current invention process. The resolution is approximately 20 nm, that is the dried ink drop approximate thickness. This technique also allows to perform diverse materials mixtures and the production of expected thickness distribution eⱼ(xᵢ, yᵢ) multilayer sets.

Once fabricated, these targets already contain all the necessary information to render the multilayer structures on many substrates, i.e. ophthalmic lenses and contact lenses, flat devices, interferential filters, multilayer coatings, gradient optical coatings, among others, and it is only needed to transfer the material, previously deposited on the target, to the corresponding substrate by means of an ionic bombardment, bombardment with ionic particles, bombardment with neutral particles or photonic bombardment or laser beam.

Advantageously, this deposition method allows controlling the deposition velocity in a very precise way and, specifically, control the deposited layers nucleation and coalescence phases evolution. This allows depositing nanometric structures and/or single atom or few atom or molecule sized thickness structures on a surface.

Depending on the substrate nature and on its surface energy, this method allows the deposition of nanometric structures or few atom clusters scattered over the substrate, according to the nucleation and growth models described by:

1. Frank van der Merwe (layer by layer growth)

2. Wolmer-Weber (island growth)

3. Stranski-Krastanov (island and layers combined growth)

This deposition method can also be used in layer-by-layer deposition processes and/or as a new modality in epitaxial growth processes like the ones used in MBE (molecular beam epitaxy).

### BRIEF DESCRIPTION OF THE DRAWINGS

In order to complement the description and with the intention of helping to a better understanding of the invention features, according to an example of practical embodiment of the said invention, a set of figures wherein, for illustrative and non-limitative purposes, is attached as a description part and parcel, in which the following has been represented:

FIG. 1 depicts a plan view of a target, with an example of mesh.

FIGS. 2 to 7 are different examples of fungible element layer structures.

FIG. 8 is a particle bombardment installation.

FIGS. 9a to 9d depict the different stages for desired thicknesses determination for each target zone.

FIG. 10a depicts a stratified target intended for the application of a target structure determination optical process.

FIG. 10b depicts a device intended to obtain target thicknesses.

FIG. 11a depicts components for the invention fungible element fabrication.

FIG. 11b depicts a section cut of an installation for the fabrication of the invention fungible element.

### DESCRIPTION OF PREFERRED EMBODIMENTS

As can be appreciated in the figures, the invention refers to a fungible element 1 provided with a target 2 for the particle bombardment, intended to carry out the vapour-phase physical deposition of a thin layer on a substrate 3, said fungible element 1 comprising a base layer 4 on which the target 2 is deposited, said target intended to be sputtered by the particle bombardment, wherein the target is formed by at least one layer 21 in which a plurality of zones (xᵢ, yᵢ) is defined, having an average thickness (eⱼ(xᵢ, yᵢ)) that is variable between the zones (xᵢ, yᵢ), said average thicknesses (eⱼ(xᵢ, yᵢ) of each zone (xᵢ, yᵢ) being dimensioned such that, in certain bombardment conditions, all the zones (xᵢ, yᵢ) have an identical ion sputtering time (tⱼ).

This is illustrated in a very simplified way in FIG. 5. Here one can appreciate two different thickness zones e₁ and e₂, which are submitted to different bombardment intensities. The element has been depicted in a convex shape, although it is not necessary to be shaped like this, for it will depend on the source yield distribution and the target yield distribution.

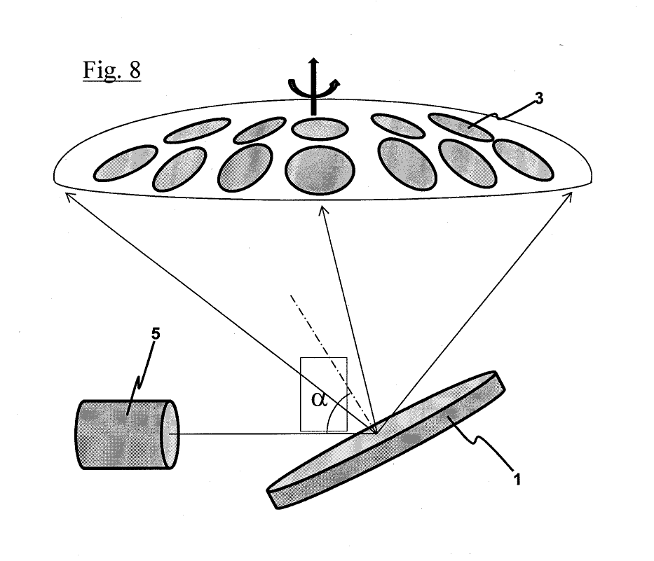

Another resulting distribution could be the one showed in FIG. 7. In some cases, especially when symmetries can be found in the installation different components and in the relative disposition between them, thickness distribution on the target will be approximate using a curve or a simple surface.

As can be appreciated in FIGS. 3, 4 and 6, the target is formed by a plurality of layers 21, 22. Layers can be homogeneous as depicted in FIGS. 2 and 3, or heterogeneous as well as depicted in FIGS. 4 and 5.

The invention, as illustrated in FIG. 8, also refers to a set formed by particle bombardment device 5 and fungible element 1 provided with a target 2 to be bombarded (with ions, neutral particles or photons) by the particle bombardment device 5 to perform vapour-phase physical deposition of a thin layer on a substrate 3 bound to receive the deposition material disposed on the target 2, said fungible element 1 comprising a base layer 4 on which said target 2 is deposited, characterized by the fact that said target 2 is constituted by at least one layer 21 in which a plurality of zones (xᵢ, yᵢ ) with an average thickness (eⱼ(xᵢ, yᵢ) that is variable between the zones (xᵢ, yᵢ), said average thicknesses (eⱼ(xᵢ, yᵢ) of each zone (xᵢ, yᵢ) being dimensioned such that, in certain bombardment conditions, all the zones (xᵢ, yᵢ) have an identical ion sputtering time (tⱼ), being so that the thickness of the layer deposited on said substrate 3 can be controlled by the previous sizing of the target 2 deposition material thicknesses (eⱼ(xᵢ, yᵢ)).

The bombardment is an ionic bombardment performed by means of a cathodic sputtering head or a plasma ion gun as well as a bombardment of neutral particles by means of a neutralized ion gun or a plasma gun.

The bombardment can also be a photonic bombardment in order to produce laser ablation (LAD) or photonic bombardment by means of pulsed laser (PLD).

As an advantageous option, the head or gun 5 comprises the means for changing its io orientation so it is possible to orient it towards the target as well as the substrate, thus having the possibility of commuting between an ion or plasma gun assisted deposition mode and a compaction by direct bombardment mode.

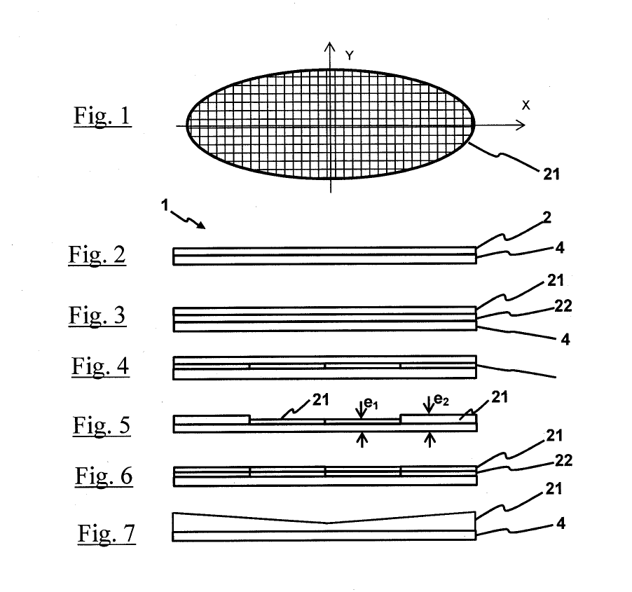

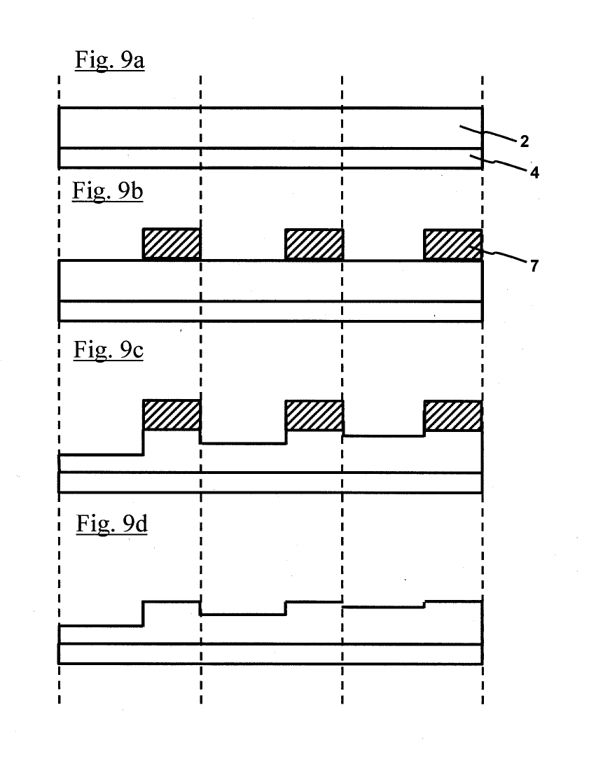

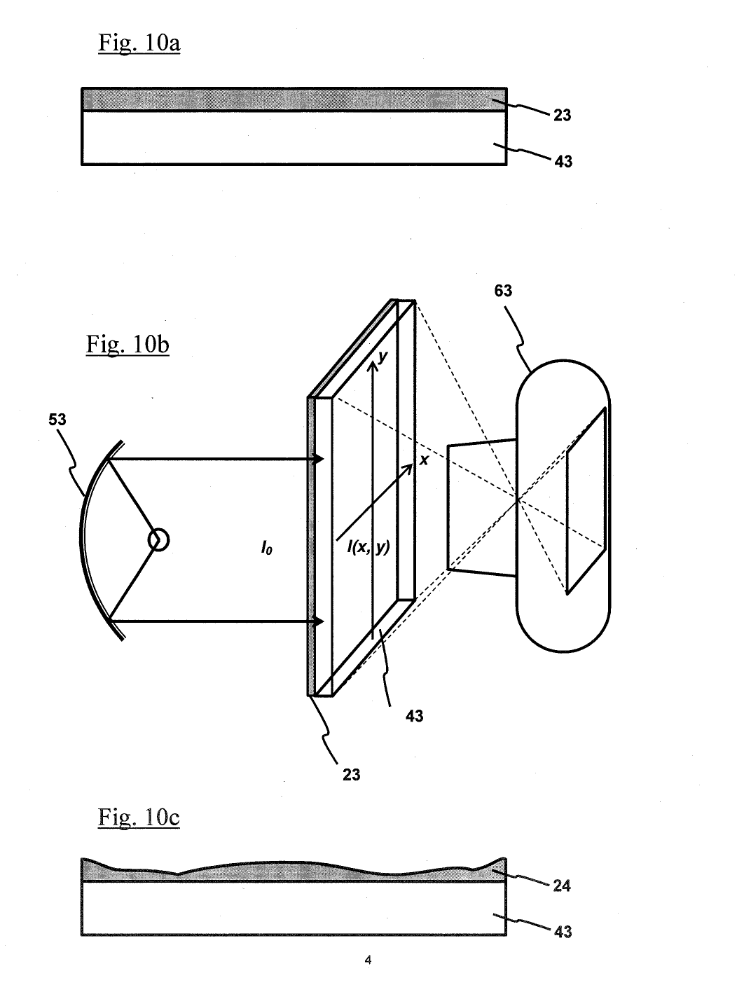

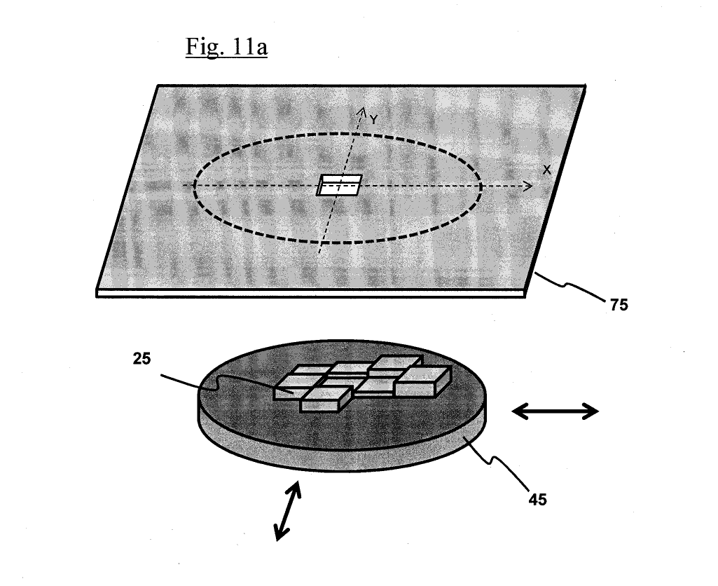

The invention also refers to a process for the determination of an engraving pattern by target 2 particles bombardment, in order to obtain an engraving velocity and thickness (eⱼ(xᵢ, yᵢ)) based on the position (x, y) of a fungible element 1 according to any of the variants depicted in FIGS. 1 to 7, comprising the stages of:
a) Perform an homogeneous deposit of deposition material on a base layer 4 to obtain a known e₀ homogeneous thickness target 2, as shown in FIG. 9a;
b) Dispose on the target 2 a resin mask 6, as depicted like a mesh in FIG. 1, so that there are zones of the target 2 that remain covered by the resin as well as zones that remain uncovered by the resin 7, as shown in FIG. 9b;
c) Dispose the resulting product during a certain amount of time, in a certain position and in front of a certain particle bombardment device 5 to perform a vapour-phase physical deposition process of a thin layer on a substrate 3, as depicted in FIG. 8, so that a target like the one depicted in FIG. 9c can be obtained;
d) Remove the resin mask 6, i.e. by dissolution, in order to obtain the product depicted in FIG. 9d;
e) Measure the local height differences between target 2 resin covered points and non resin covered points 7, which is possible using the target depited in FIG. 9d;
f) Obtain an engraving velocity function vⱼ(xᵢ, yᵢ) of the target (2) for the aforementioned certain conditions;
g) Use the said engraving velocity function vⱼ(xᵢ, yᵢ) to determine the thickness (eⱼ(xᵢ, yᵢ)) of the target in every position (x,y) so that the layer or layers (j) of the fungible element can be consumed one after another.
   An optical process with similar results can be performed following the stages of:
a) Perform a deposition, distinguished by a certain optical absorption, α(λ), where λ is the wavelength, over a transparent base layer 43 in order to obtain an homogeneous thickness target 23, distinguished by a certain optical absorption, α(λ), as depicted in FIG. 10a;
b) Dispose the transparent base layer 43 with the homogeneous thickness target 23, distinguished by a certain optical absorption, α(λ), in an I₀ intensity, normal incidence illumination device with a lamp 53, i.e. with white light or monochromatic light of I₀ intensity, as depicted in FIG. 10b;
c) Obtain a photographic image by means of a photographic device 63, of the posterior part of the system integrated by the transparent base 43 and the homogeneous thickness target 23 and α(λ) optical absorption, when crossed by an incident light beam of I₀ intensity, which is partially absorbed according to Alambert law:

I(x,y)=I₀·exp[−α·e(x,y)]

where I(x,y) is the intensity of the light transmitted by the system integrated by the transparent base 43 and the homogeneous thickness target 23 and α(λ) optical absorption, where the variables (x, y) are the target 23 coordinates, and e(x, y) the thickness of the target 23 in every position after the sputtering by particle bombardment;
d) Dispose the product obtained in a) during a certain amount of time, in a certain position and in front of a certain particle bombardment device 5 to carry out the vapour-phase physical deposition of a thin layer on a substrate 3, as shown in FIG. 8, in such a way that a target like the one depicted in FIG. 9c is obtained;
e) Determine the relation IF(x,y)/IF₀(x,y) point by point, of the given intensity in every pixel of the target 2 photographic images, before, IF₀(x, y), and after, IF(x,y), the particle bombardment by sputtering, performed for example by means of image treatment common techniques as well as techniques of matrix calculation using the image pixels as matrix elements.
f) Assuming the linearity of the photographic image collected intensities regarding the light beam intensity:

IF(x,y)=k·l(x,y)

where k is a constant, in order to determine the target 24 thickness after being sputtered by the particle bombardment, based on position (x,y) using the expression:

$$e ( x , y ) = \frac{1}{α} ln \frac{{IF}_{0} ( x , y )}{IF ( x , y )}$$

g) Obtain an engraving velocity function v(x, y) for the target 24 for the aforementioned certain conditions;
h) Use the engraving velocity function v(x, y) to determine the thickness e(x, y) of every target position (x,y) so that the layer or layers of the fungible element can be consumed one after another.
i) Utilize image treatment software for, by means of the appropriate filters and the obtained thickness function e(x, y), and generate constant thickness domains Dᵢ, eⱼ(xᵢ, yᵢ) and arbitrary dimensions, that cover the target 24 surface.

These processes can be performed in a systematic way, that is they can easily become a protocol or even be automated.

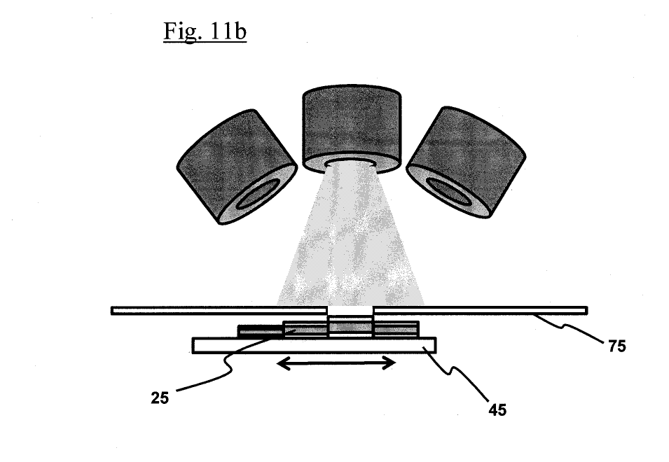

The invention also refers to a process to fabricate the fungible element 1, after the determination of the engraving velocity vᵢ(xᵢ, yᵢ), by means of physical vapour deposition (PVD) techniques or chemical vapour deposition (CVD) techniques, to obtain monolayer or multilayer structures on a base layer 45, as shown in FIG. 11a, which comprises the stages of:
a) Perform a PVD or CVD deposition using a mask 75, with a Dᵢ domain sized aperture, attached on a base layer 45, with adjustable (x, y) position, in order to obtain a monolayer or multilayer target 25 with eⱼ(xᵢ, yᵢ) thickness domains, as shown in FIG. 11b;
b) Perform the material deposition in order to obtain a monolayer or multilayer target 25 by means of PVD or CVD process, using a mask 75 attached to the base layer 45, sequentially by moving the base 45 over every Dᵢ domain, and keeping on the deposition process over every Dᵢ domain during a τᵢⱼ(xᵢ, yᵢ), time period, determined by the following expression:

$${τ}_{ij} ( {x}_{i} , {y}_{i} ) = {P}_{ij} {M}_{ij} {L}_{ij} \frac{{e}_{i} ( {x}_{i} , {y}_{i} )}{{v}_{i} ( {x}_{i} , {y}_{i} )}$$

where Pᵢⱼ, Mᵢⱼ y Lᵢⱼ are constants determined respectively by the type of material deposited on each layer of the target 25 multilayer system, by the PVD or CVD process conditions of each layer of the target 25 multilayer system and the final thicknesses of each desired material layer and the initial thickness obtained during the process of determination of the particle bombardment engraving pattern, where the subscripts i and j indicate respectively the domain and the multilayer system layer number to be obtained for the target 25 fabrication.
c) For the calculation of the constants Pᵢⱼ, Mᵢⱼ y Lᵢⱼ, a PVD or CVD deposition velocity calibration process is performed for each material to be used.
   The invention is not limited to the specific embodiments previously described but also comprises, for example, the variants that can be performed by the skilled person, always remaining within the scope of the claims.

1. A fungible element (1) provided with a target (2) for the particle bombardment, intended to carry out the vapour-phase physical deposition of a thin layer on a substrate (3), said fungible element (1) comprising a base layer (4) on which the target (2) is deposited, said target intended to be sputtered by the particle bombardment, wherein the target is formed by at least one layer (21) in which a plurality of zones (xᵢ, yᵢ) is defined, having an average thickness (eⱼ(xᵢ, yᵢ)) that is variable between the zones (xᵢ, yᵢ), said average thickness (eⱼ(xᵢ, yᵢ)) of each zone (xᵢ, yᵢ) being dimensioned such that, in certain bombardment conditions, all the zones (xᵢ, yᵢ) have an identical ion sputtering time (tⱼ).

2. The element according to claim 1, wherein the target is constituted by a plurality of layers (21, 22).

3. The element of claim 1, wherein the zones (xᵢ, yᵢ), can be composed by the same material as well as by different materials.

4. A system formed by particle bombardment device (5) and fungible element (1) provided with a target (2) to be bombarded by the particle bombardment device (5) to perform vapour-phase physical deposition of a thin layer on a substrate (3) bound to receive the deposition material disposed on the target (2), said fungible element (1) comprising a base layer (4) on which said target (2) is deposited, wherein said target (2) is constituted by at least one layer (21) in which a plurality of zones (xᵢ, yᵢ) with an average thickness (eⱼ(xᵢ, yᵢ)) that is variable between the zones (xᵢ, yᵢ), said average thicknesses (eⱼ(xᵢ, yᵢ)) of each zone (xᵢ, yᵢ) being dimensioned such that, in certain bombardment conditions, all the zones (xᵢ, yᵢ) have an identical ion sputtering time (tⱼ), being so that the thickness of the layer deposited on said substrate (3) can be controlled by the previous sizing of the target (2) deposition material thicknesses (eⱼ(xᵢ, yᵢ).

5. The fungible element according to claim 1, wherein the target is constituted by a plurality of layers (21, 22).

6. The system according to claim 4 wherein the zones (xᵢ, yᵢ) can be composed by the same material as well as by different materials.

7. The system according to claim 4, in which bombardment is an ionic bombardment performed by means of a cathodic sputtering head or a plasma ion gun as well as a bombardment of neutral particles by means of a neutralized ion gun or a plasma gun.

8. The system according to claim 4, in which bombardment is a photonic bombardment in order to produce laser ablation (LAD) or photonic bombardment by means of pulsed laser (PLD).

9. The system according to claim 7, in which the head or gun comprises the means for changing its orientation so it is possible to orient it towards the target as well as the substrate, thus having the possibility of commuting between an ion or plasma gun assisted deposition mode and a compaction by direct bombardment mode.

10. A process for determining an engraving pattern by target (2) particles bombardment, in order to obtain an engraving velocity and thickness (eⱼ(xᵢ, yᵢ)) based on the position (x, y) of a fungible element (1) according to claim 1 comprising the steps stages of:
a) perform an homogeneous deposit of deposition material on a base layer (4) to obtain an homogeneous thickness target (2);
b) dispose on the target (2) a resin mask (6), so that there are zones of the target (2) that remain covered by the resin as well as zones that remain uncovered by the resin (7);
c) dispose the resulting product during a certain amount of time, in a certain position and in front of a certain particle bombardment device (5) to perform a vapour-phase physical deposition process of a thin layer on a substrate (3);
d) the resin mask (6);
e) measure the local height differences between target (2) resin covered points and non resin covered points (7);
f) obtain an engraving velocity function vⱼ(xᵢ, yᵢ) of the target (2) for the aforementioned certain conditions;
g) use the said engraving velocity function vⱼ(xᵢ, yᵢ) to determine the thickness (eⱼ(xᵢ, yᵢ)) of the target in every position (x,y) so that the layer or layers (j) of the fungible element can be consumed one after another.

11. The process according to claim 10, in which the mask (7) is a mesh.

12. A process for determining a pattern by target (2) particles bombardment, for obtaining of engraving velocity and thickness (eⱼ(xᵢ, yᵢ)) based on the position (x, y) of a fungible element (1) according to claim 1, comprising the steps stages of:
a) perform a deposition, distinguished by a certain optical absorption, α(λ), where is the wavelength, over a transparent base layer (43) in order to obtain an homogeneous thickness target (23), distinguished by a certain optical absorption, α(λ);
b) dispose the transparent base layer (43) with the homogeneous thickness target (23), distinguished by a certain optical absorption, α(λ), in an I₀ intensity, normal incidence illumination device with a lamp (53);
c) obtain a photographic image by means of a photographic device (63), of the posterior part of the system integrated by the transparent base (43) and the homogeneous thickness target (23) and α(λ) optical absorption, when crossed by an incident light beam of I₀ intensity, which is partially absorbed according to Alambert law:
I(x,y)=I₀·exp[−α·e(x,y)]
where I(x, y) is the intensity of the light transmitted by the system integrated by the transparent base (43) and the homogeneous thickness target (23) and α(λ) optical absorption, where the variables (x, y) are the target (23) coordinates, and e(x, y) the thickness of the target (23) in every position after the sputtering by particle bombardment;
d) dispose the product obtained in a) during a certain amount of time, in a certain position and in front of a certain particle bombardment device (5) to carry out the vapour-phase physical deposition of a thin layer on a substrate (3);
e) determine the relation IF(x, y)/IF₀(x, y) point by point, of the given intensity in every pixel of the target (2) photographic images, before, IF₀(x,y), and after, IF(x, y), the particle bombardment by sputtering.
f) assume the linearity of the photographic image collected intensities regarding the light beam intensity:
IF(x,y)=k·I(x,y)
where k is a constant, in order to determine the target (24) thickness after being sputtered by the particle bombardment, based on position (x,y) using the expression:
$$e ( x , y ) = \frac{1}{α} ln \frac{{IF}_{0} ( x , y )}{IF ( x , y )}$$
g) obtain an engraving velocity function v(x, y) for the target (24) for the aforementioned certain conditions;
h) use the engraving velocity function v(x, y) to determine the thickness e(x, y) of every target position (x,y) so that the layer or layers of the fungible element can be consumed one after another.
i) utilize image treatment software for, by means of the appropriate filters and the obtained thickness function e(x, y), and generate constant thickness domains Dᵢ, eⱼ(xᵢ, yᵢ) and arbitrary dimensions, that cover the target (24) surface.

13. The process according to claim 12, in which the deposition of stage a) is homogeneous and formed by a semitransparent deposition material.

14. The process according to claim 13, in which the deposition is a very thin metal layer of about some tens of nanometers, as well as a semitransparent material with a non null optical transmittance specter, such as a semiconductor material, or a semitransparent dielectric.

15. The process according to claim 12, in which the stage b) is performed with white light or monochromatic light of I₀ intensity.

16. The process according to claim 12 in which stage e) is performed by means of image treatment common techniques as well as techniques of matrix calculation using the image pixels as matrix elements.

17. A process to fabricate a fungible element (1), after the determination of the engraving velocity vᵢ(xᵢ, yᵢ), by means of physical vapour deposition (PVD) techniques or chemical vapour deposition (CVD) techniques, to obtain monolayer or multilayer structures on a base layer (45), which comprises the steps of:
a) perform a PVD or CVD deposition using a mask (75), with a Dᵢ domain sized aperture, attached on a base layer (45), with adjustable (x, y) position, in order to obtain a monolayer or multilayer target (25) with eⱼ(xᵢ, yᵢ) thickness domains;
b) perform the material deposition in order to obtain a monolayer or multilayer target (25) by means of PVD or CVD process, using a mask (75) attached to the base layer (45), sequentially by moving the base (45) over every Dᵢ domain, and keeping on the deposition process over every Dᵢ domain during a τᵢⱼ(xᵢ, yᵢ), time period, determined by the following expression:
$${τ}_{ij} ( {x}_{i} , {y}_{i} ) = {P}_{ij} {M}_{ij} {L}_{ij} \frac{{e}_{i} ( {x}_{i} , {y}_{i} )}{{v}_{i} ( {x}_{i} , {y}_{i} )}$$
where Pᵢⱼ, Mᵢⱼ y Lᵢⱼ are constants determined respectively by the type of material deposited on each layer of the target (25) multilayer system, by the PVD or CVD process conditions of each layer of the target (25) multilayer system and the final thicknesses of each desired material layer and the initial thickness obtained during the process of determination of the particle bombardment engraving pattern, where the subscripts i and j indicate respectively the domain and the multilayer system layer number to be obtained for the target (25) fabrication.

18. The process according to claim 17, in which the mask (75) is formed by a rigid material, preferably metallic.

19. The process according to claim 17 in which a single process or a repetitive process is performed in the stage b).

20. The process according to claim 17 in which for the calculation of the constants Pᵢⱼ, Mᵢⱼ y Lᵢⱼ, a PVD or CVD deposition velocity calibration process is performed for each material to be used.
